(19) United States
(12) Patent Application Publication
(10) Pub. No.: US 2021/0382442 A1
(43) Pub. Date: Dec. 9, 2021

(54) DEVICE WITH A NOISE SHAPING FUNCTION IN GAIN CONTROL

(71) Applicant: BlueX Microelectronics ( Hefei ) Co., Ltd., Hefei City (CN)

(72) Inventors: Hao-Ming Chen, Hsinchu County (TW); Yi-Chun Lu, Hsinchu County (TW); HONGYU LI, Palo Alto, CA (US)

(21) Appl. No.: 16/896,230

(22) Filed: Jun. 9, 2020

(51) Int. Cl. G05B 13/02; H03K 3/037

(52) U.S. Cl. CPC G05B 13/024; H03K 3/037

(57) ABSTRACT

A device with a noise shaping function in gain control includes a first adder, an N-bit quantizer, a mapping circuit, a second adder, a first D flip-flop, a scaler, and a second D flip-flop. The first adder generates a first value according to an input signal, a second value, and a third value. The N-bit quantizer outputs a codeword to a controller according to the first value. Adjusting orders corresponding to codewords outputted by the N-bit quantizer are between a smallest predetermined negative value and a largest positive predetermined value, the controller utilizes an adjusting order corresponding to the codeword to make a signal generator generate a signal with adjusted power, and N is an integer greater than 2. The first D flip-flop, the scaler, and the second D flip-flop are used for providing a high-pass filter effect to the device.

### BACKGROUND OF THE INVENTION

### 1. Field of the Invention

The present invention relates to a device in gain control, and particularly to a device with a noise shaping function in gain control.

### 2. Description of the Prior Art

When a signal generator generates a signal 51 (shown in FIG. 1), a power adjuster 10 (shown in FIG. 1) within the signal generator can adjust power of the signal 51 to make the signal generator generate the signal 51 with adjusted power.

As shown in FIG. 1, first a power detector 16 of the power adjuster 10 can detect power PO of the signal 51, then a gain mapping circuit 14 of the power adjuster 10 can generate an adjusted gain AG according to the power PO and target power TP, and then a multiplier 12 of the power adjuster 10 can multiply the signal 51 and the adjusted gain AG to generate an adjusted signal AS. If power of the adjusted signal AS is still not equal to the target power TP, the above-mentioned operation will be executed repeatedly until the power of the adjusted signal AS is equal to the target power TP.

Although the power adjuster 10 can adjust power of the signal 51 step by step until the power of the adjusted signal AS is equal to the target power TP, noise is caused by discontinuous change of the power of the adjusted signal AS during a process of the power of the adjusted signal AS being gradually close to the target power TP. Therefore, how to suppress the noise during the process of the process of the power of the adjusted signal AS being gradually close to the target power TP becomes an important issue.

### SUMMARY OF THE INVENTION

An embodiment of the present invention provides a device with a noise shaping function in gain control. The device includes a first adder, an N-bit quantizer, a mapping circuit, a second adder, a first D flip-flop, a scaler, and a D flip-flop. The first adder is used for generating a first value according to an input signal, a second value, and a third value. The N-bit quantizer is coupled to the first adder for outputting a codeword to a controller according to the first value, wherein the codeword is mapped to an adjusting order, adjusting orders corresponding to codewords outputted by the N-bit quantizer are between a smallest predetermined negative value and a largest positive predetermined value, the controller generates a control signal to a signal generator according to the adjusting order, the signal generator adjusts a current power of a signal to generate the signal with adjusted power according to the control signal, and N is an integer greater than 2. The mapping circuit is coupled to the N-bit quantizer for outputting a mapping value according to the codeword. The second adder is coupled to the first adder, the N-bit quantizer, and the mapping circuit for generating the second value according to the mapping value and the first value. The first D flip-flop is coupled to the second adder for latching the second value. The scaler is coupled to the first D flip-flop and the first adder for scaling the second value to generate the third value. The second D flip-flop is coupled to the first adder, the scaler, and the first D flip-flop for latching the second value and outputting the second value to the first adder.

Another embodiment of the present invention provides a device with a noise shaping function in gain control. The device includes a first adder, a controller, a signal generator, an N-bit quantizer, a mapping circuit, a second adder, a first D flip-flop, a scaler, and a D flip-flop. The first adder is used for generating a first value according to an input signal, a second value, and a third value. The N-bit quantizer is coupled to the first adder for outputting a codeword to the controller according to the first value, wherein the codeword is mapped to an adjusting order, adjusting orders corresponding to codewords outputted by the N-bit quantizer are between a smallest predetermined negative value and a largest positive predetermined value, the controller generates a control signal to the signal generator according to the adjusting order, the signal generator adjusts a current power of a signal to generate the signal with adjusted power according to the control signal, and N is an integer greater than 2. The mapping circuit is coupled to the N-bit quantizer for outputting a mapping value according to the codeword. The second adder is coupled to the first adder, the N-bit quantizer, and the mapping circuit for generating the second value according to the mapping value and the first value. The first D flip-flop is coupled to the second adder for latching the second value. The scaler is coupled to the first D flip-flop and the first adder for scaling the second value to generate the third value. The second D flip-flop is coupled to the first adder, the scaler, and the first D flip-flop for latching the second value and outputting the second value to the first adder.

The present invention provides a device with a noise shaping function in gain control. The present invention first makes change of adjusted power be discontinuous, and then utilizes differentiation characteristic and the high-pass filter effect characteristic of the device to make noise caused by the discontinuous change of the adjusted power be moved to a higher frequency outside a frequency range utilized by an integrated circuit. Therefore, compared to the prior art, noise fallen in the frequency range utilized by the integrated circuit can be effectively suppressed because the noise caused by the discontinuous change of the adjusted sampling frequency has been moved to the higher frequency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a power adjuster according to the prior art.

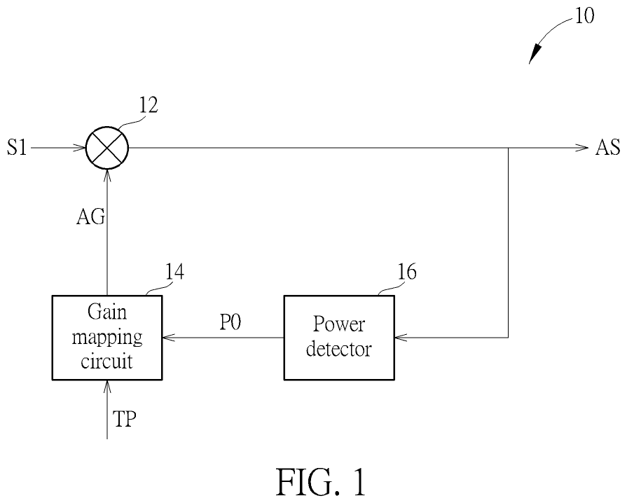

FIG. 2 is a diagram illustrating a device with a noise shaping function in gain control according to an embodiment of the present invention.

### DETAILED DESCRIPTION

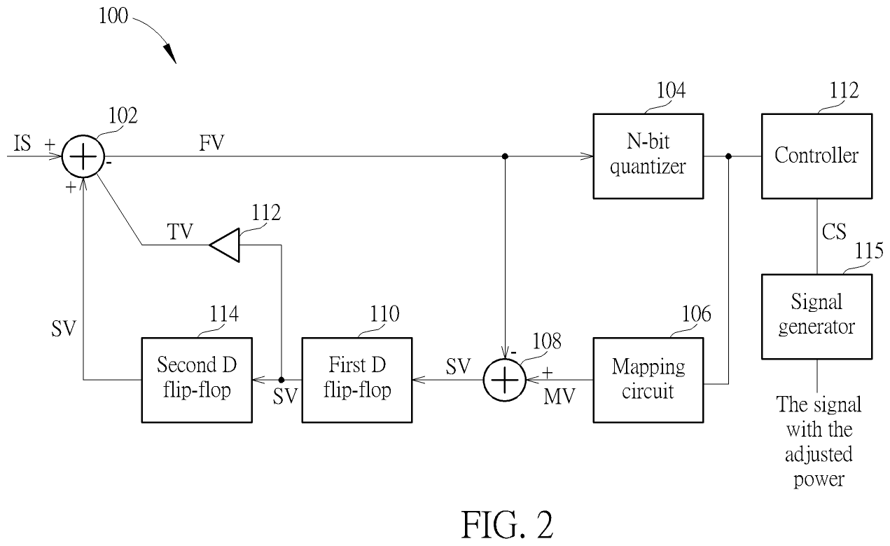

Please refer to FIG. 2. FIG. 2 is a diagram illustrating a device 100 according to an embodiment of the present invention, wherein the device 100 has a noise shaping function in gain control, and the device 100 is a second-order Sigma-Delta (ΣΔ) modulation circuit. But, the present invention is not limited to the device 100 being the second-order Sigma-Delta (ΣΔ) modulation circuit. That is to say, the device 100 can be a high-order (more than second order) Sigma-Delta (ΣΔ) modulation circuit.

As shown in FIG. 2, the device 100 includes a first adder 102, an N-bit quantizer 104, a mapping circuit 106, a second adder 108, and a first D flip-flop 110, a scaler 112, and a second D flip-flop 114, wherein the N-bit quantizer 104 is coupled to the first adder 102, the mapping circuit 106 is coupled to the N-bit quantizer 104, the second adder 108 is coupled to the first adder 102, the N-bit quantizer 104, and the mapping circuit 106, the first D flip-flop 110 is coupled to the second adder 108, the scaler 112 is coupled to the first D flip-flop 110 and the first adder 102, the second D flip-flop 114 is coupled to the first adder 102, the scaler 112, and the first D flip-flop 110, and N is an integer greater than 2.

As shown in FIG. 2, the first adder 102 is used for generating a first value FV according to an input signal INS, a second value SV, and a third value TV, wherein the input signal INS corresponds to a difference between a target power to a current power of a signal, wherein the signal is generated by a signal generator 115, and the first adder 102 subtracts the third value TV from a sum of the input signal INS and the second value SV. In addition, the signal can be a wireless signal, wired signal, optical signal, sound signal, and so on. After the N-bit quantizer 104 receives the first value FV, the N-bit quantizer 104 can output a codeword to a controller 116 according to the first value FV, wherein the controller 116 can map the codeword to an adjusting order according to TABLE I stored in a lookup table of the controller 116. After the controller 116 maps the codeword to the adjusting order, the controller 116 can generate a control signal CS to the signal generator 115 according to the adjusting order. After the signal generator 115 receives the control signal CS, the signal generator 115 can adjust the current power of the signal to generate the signal with adjusted power according to the control signal CS and output the signal with the adjusted power, wherein the adjusted power can be greater or less than the current power depending on the target power. That is, when the current power is less than the target power, the adjusted power is greater than the current power; when the current power is greater than the target power, the adjusted power is less than the current power. In addition, the device 100, the controller 116, and the signal generator 115 can be applied to an integrated circuit (e.g. a communication integrated circuit, an audio integrated circuit, or a sensing integrated circuit). TABLE I is shown as follows, wherein a can be a constant (e.g. 0.125 dB):

TABLE I

| Codeword | Adjusting order |
|---|---|
| 0 | −2^{(N-1)} * α |
| 1 | −(2^{(N-1)} − 1) * α |
| 2 | −(2^{(N-1)} − 2) * α |
| . | . |
| . | . |
| . | . |
| 2^{(N-1)} | 0 |
| . | . |
| . | . |
| . | . |
| 2^{N} − 2 | (2^{(N-1)} − 2) * α |
| 2^{N} − 1 | (2^{(N-1)} − 1) * α |

As shown in TABLE I, adjusting orders are between a smallest predetermined negative value (i.e. −2^{(N-1)}*α) and a largest positive predetermined value (i.e. (2^{(N-1)}−1)*α), the adjusting orders are increased from the smallest predetermined negative value (i.e. −2^{(N-1)}*α) to the largest positive predetermined value (i.e. (2^{(N-1)}−1)*α), and it is obvious that the smallest predetermined negative value (i.e. −2^{(N-1)}*α) and the largest positive predetermined value (i.e. (2^{(N-1)}−1)^{*α}) correspond to N. In addition, as shown in TABLE I, a number of codewords outputted by the N-bit quantizer 104 is 2^{N}, a smallest codeword of the codewords is 0, a largest codeword of the codewords is 2^{N}−1, each codeword of the codewords is an integer, and the codewords are increased from the smallest codeword (i.e. 0) to the largest codeword (i.e. 2^{N}−1).

As shown in TABLE I, each codeword of the codewords corresponds to one adjusting order of the adjusting orders. For example, if N is equal to 3, a number of the codewords outputted by the N-bit quantizer 104 is 2³ (=8). That is, if N is equal to 3, the codeword can be 0, 1, 2, 3, . . . , 7, wherein the codeword (0) corresponds to the adjusting order (−2⁽³⁻¹⁾*α), the codeword (1) corresponds to the adjusting order (−(2⁽³⁻¹⁾−1)*α), the codeword (7) corresponds to the adjusting order ((2⁽³⁻¹⁾−1)*α), and so on.

In addition, the present invention is not limited to general forms (shown in TABLE I) of the adjusting orders, that is, the adjusting orders can have another general forms (shown in TABLE II). TABLE II is shown as follows, wherein M is a positive constant value, and M can be an integer or not:

TABLE II

| Codeword | Adjusting Order |
|---|---|
| 0 | −M^{(N-1)} * α |
| 1 | −(M^{(N-1)} − 1) * α |
| 2 | −(M^{(N-1)} − 2) * α |
| . | . |
| . | . |
| . | . |
| 2^{(N-1)} | 0 |
| . | . |
| . | . |
| . | . |
| 2^{N} − 2 | (M^{(N-1)} − 2) * α |
| 2^{N} − 1 | (M^{(N-1)} − 1) * α |

Therefore, any configuration in which the adjusting orders are increased from the smallest predetermined negative value (i.e. −2^{(N-1)}*α) to the largest positive predetermined value (i.e. (2^{(N-1)}−1)*α) falls within the scope of the present invention.

As shown in FIG. 2, after the mapping circuit 106 receives the codeword outputted by the N-bit quantizer 104, the mapping circuit 106 can output a mapping value MV according to the codeword, wherein the mapping value MV is between 1 and −1. For example, if N is equal to 3, the mapping value MV can be one of −⅞, −⅝, −⅜, −⅛, ⅛, ⅜, ⅝, ⅞.

As shown in FIG. 2, the second adder 108 can subtract the first value from the mapping value MV to generate the second value SV. Then, the first D flip-flop 110 latches the second value SV and outputting the second value SV to the scaler 112 and the second D flip-flop 114, and the scaler 112 is used for scaling the second value SV to generate the third value TV, wherein the first D flip-flop 110, the scaler 112, and the second D flip-flop 114 are used for providing a high-pass filter effect to the device 100.

In addition, each adjusting order of the adjusting orders can correspond to one gain adjusting level (expressed in Decibel (dB)). For example, in one embodiment of the present invention, if N is equal to 3 and α is 0.125 dB, the adjusting order (−2⁽³⁻¹⁾*α) corresponds to the gain adjusting level (−0.5 dB), the adjusting order (−(2⁽³⁻¹⁾−1)*α) corresponds to the gain adjusting level (−0.375 dB), the adjusting order (−(2⁽³⁻¹⁾−2)*α) corresponds to the gain adjusting level (−0.25 dB), the adjusting order (−(2⁽³⁻¹⁾−3)*α) corresponds to the gain adjusting level (−0.125 dB), the adjusting order (−(2⁽³⁻¹⁾−4)*α, i.e. 0) corresponds to the gain adjusting level (0 dB), the adjusting order (2⁽³⁻¹⁾−3)*α corresponds to the gain adjusting level (0.125 dB), the adjusting order (2⁽³⁻¹⁾−2)*α corresponds to the gain adjusting level (0.25 dB), and the adjusting order (2⁽³⁻¹⁾−1)*α corresponds to the gain adjusting level (0.375 dB). But, the present invention is not limited to the above-mentioned corresponding relationships between the adjusting orders and the gain adjusting levels.

Therefore, after the controller 116 receives the codeword outputted by the N-bit quantizer 104, the controller 116 can first map the codeword to an adjusting order according to TABLE I, then map the adjusting order to a gain adjusting level, and then generate the control signal CS corresponding to the gain adjusting level. Finally, the controller 116 can apply the control signal CS to the signal generator 115 to make the signal generator 115 generate and output the signal with the adjusted power according to the control signal CS.

For example, when the current power is less than the target power, the first adder 102 can generate the first value FV according to the input signal INS, the second value SV, and the third value TV. The N-bit quantizer 104 will output a codeword according to the first value FV. Meanwhile, the codeword outputted by the N-bit quantizer 104 can make an adjusting order mapped by the controller 116 according to the codeword outputted by the N-bit quantizer 104 be a positive predetermined value (e.g. (2⁽³⁻¹⁾−2)*α. Then, the controller 116 maps the positive predetermined value (e.g. (2⁽³⁻¹⁾−2)*α to a gain adjusting level (i.e. 0.25 dB) and generates the control signal CS corresponding to the gain adjusting level (i.e. 0.25 dB) to the signal generator 115. Therefore, after the signal generator 115 receives the control signal CS corresponding to the gain adjusting level (i.e. 0.25 dB), the signal generator 115 can generate the signal with the adjusted power according to the control signal CS, wherein the adjusted power corresponds to the gain adjusting level (i.e. 0.25 dB) and the current power, and the adjusted power will be greater than the current power. If the adjusted power is still less than the target power, the above-mentioned operation will be executed repeatedly until the adjusted power is equal to the target power.

In addition, when the current power is greater than the target power, the first adder 102 can generate the first value FV according to the input signal INS, the second value SV, and the third value TV. The N-bit quantizer 104 will output a codeword according to the first value FV. Meanwhile, the codeword outputted by the N-bit quantizer 104 can make an adjusting order mapped by the controller 116 according to the codeword outputted by the N-bit quantizer 104 a negative predetermined value (e.g. −(2⁽³⁻¹⁾−2)*α). Then, the controller 116 maps the negative predetermined value (e.g. −(2⁽³⁻¹⁾−2)*α) to a gain adjusting level (i.e. −0.25 dB) and generates the control signal CS corresponding to the gain adjusting level (i.e. −0.25 dB) to the signal generator 115. Therefore, after the signal generator 115 receives the control signal CS corresponding to the gain adjusting level (i.e. −0.25 dB), the signal generator 115 can generate the signal with the adjusted power according to the control signal CS, wherein the adjusted power corresponds to the gain adjusting level (i.e. −0.25 dB) and the current power, and the adjusted power will be less than the current power. If the adjusted power is still greater than the target power, the above-mentioned operation will be executed repeatedly until the adjusted power is equal to the target power.

Because during a process of the device 100, the controller 116, and the signal generator 115 making the adjusted the adjusted power be equal to the target power according to TABLE I, TABLE I can make change of the adjusted power be discontinuous, differentiation characteristic and high-pass filter effect characteristic of the device 100 can make noise caused by discontinuous change corresponding to the adjusted power be moved to a higher frequency (that is, the noise shaping function), resulting in noise fallen in a frequency range utilized by the integrated circuit being effectively suppressed, wherein the higher frequency is outside the frequency range utilized by the integrated circuit, resulting in a resolution of the signal generated by the signal generator 115 being increased.

In addition, one of ordinary skill in the art should clearly realize functions of the first adder 102, the N-bit quantizer 104, the mapping circuit 106, the second adder 108, the first D flip-flop 110, the scaler 112, the second D flip-flop 114, and the controller 116 through the above-mentioned corresponding descriptions of the first adder 102, the N-bit quantizer 104, the mapping circuit 106, the second adder 108, the first D flip-flop 110, the scaler 112, the second D flip-flop 114, and the controller 116, so one of ordinary skill in the art can easily implement the first adder 102, the N-bit quantizer 104, the mapping circuit 106, the second adder 108, the first D flip-flop 110, the scaler 112, the second D flip-flop 114, and the controller 116 through field programmable gate arrays (FPGAs) with the above-mentioned functions of the first adder 102, the N-bit quantizer 104, the mapping circuit 106, the second adder 108, the first D flip-flop 110, the scaler 112, the second D flip-flop 114, and the controller 116 respectively, or application-specific integrated circuits (ASICs) with the above-mentioned functions of the first adder 102, the N-bit quantizer 104, the mapping circuit 106, the second adder 108, the first D flip-flop 110, the scaler 112, the second D flip-flop 114, and the controller 116 respectively, or software modules with the above-mentioned functions of the first adder 102, the N-bit quantizer 104, the mapping circuit 106, the second adder 108, the first D flip-flop 110, the scaler 112, the second D flip-flop 114, and the controller 116 respectively, or analog integrated circuits with the above-mentioned functions of the first adder 102, the N-bit quantizer 104, the mapping circuit 106, the second adder 108, the first D flip-flop 110, the scaler 112, the second D flip-flop 114, and the controller 116 respectively. Moreover, because one of ordinary skill in the art can input codes of the above mentioned functions of the first adder 102, the N-bit quantizer 104, the mapping circuit 106, the second adder 108, the first D flip-flop 110, the scaler 112, the second D flip-flop 114, and the controller 116 to the FPGAs, or utilize intellectual property cores (IPs) of the above mentioned functions of the first adder 102, the N-bit quantizer 104, the mapping circuit 106, the second adder 108, the first D flip-flop 110, the scaler 112, the second D flip-flop 114, and the controller 116 to implement the ASICs, and the FPGAs and the IPs are obviously ready-made to one of ordinary skill in the art. Therefore, further descriptions of corresponding structures of the first adder 102, the N-bit quantizer 104, the mapping circuit 106, the second adder 108, the first D flip-flop 110, the scaler 112, the second D flip-flop 114, and the controller 116 are omitted for simplicity.

In addition, in one embodiment of the present invention, the device 100, the controller 116, and the signal generator 115 are installed in the integrated circuit.

To sum up, because the present invention first makes the change of the adjusted power be discontinuous, and then utilizes the differentiation characteristic and the high-pass filter effect characteristic of the device to make the noise caused by the discontinuous change of the adjusted power be moved to the higher frequency outside the frequency range utilized by the integrated circuit, compared to the prior art, the noise fallen in the frequency range utilized by the integrated circuit can be effectively suppressed because the noise has been moved to the higher frequency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A device with a noise shaping function in gain control, comprising:
a first adder for generating a first value according to an input signal, a second value, and a third value;
an N-bit quantizer coupled to the first adder for outputting a codeword to a controller according to the first value, wherein the codeword is mapped to an adjusting order, adjusting orders corresponding to codewords outputted by the N-bit quantizer are between a smallest predetermined negative value and a largest positive predetermined value, the controller generates a control signal to a signal generator according to the adjusting order, the signal generator adjusts a current power of a signal to generate the signal with adjusted power according to the control signal, and N is an integer greater than 2;
a mapping circuit coupled to the N-bit quantizer for outputting a mapping value according to the codeword;
a second adder coupled to the first adder, the N-bit quantizer, and the mapping circuit for generating the second value according to the mapping value and the first value;
a first D flip-flop coupled to the second adder for latching the second value;
a scaler coupled to the first D flip-flop and the first adder for scaling the second value to generate the third value; and
a second D flip-flop coupled to the first adder, the scaler, and the first D flip-flop for latching the second value and outputting the second value to the first adder.

2. The device of claim 1, wherein the input signal corresponds to a difference between a target power to the current power of the signal.

3. The device of claim 1, wherein the device is a second-order Sigma-Delta (ΣΔ) modulation circuit.

4. The device of claim 1, wherein a number of the codewords is 2^{N}, a smallest codeword of the codewords is 0, a largest codeword of the codewords is 2^{N}−1, and the codewords are increased from the smallest codeword to the largest codeword.

5. The device of claim 1, wherein the smallest predetermined negative value and the largest positive predetermined value correspond to N.

6. The device of claim 1, wherein the smallest predetermined negative value is −2^{(N-1)} and the largest positive predetermined value is 2^{(N-1)}−1.

7. The device of claim 1, wherein the adjusting orders are increased from the smallest predetermined negative value to the largest positive predetermined value.

8. The device of claim 1, wherein the mapping value is between 1 and −1.

9. The device of claim 1, wherein the controller maps the adjusting order to a gain adjusting level and further makes the signal generator adjust the current power of the signal to generate the signal with the adjusted power according to the gain adjusting level.

10. The device of claim 1, wherein the adjusting orders makes a change of the adjusted power be discontinuous.

11. The device of claim 1, wherein differentiation characteristic and high-pass filter effect characteristic of the device make noise caused by discontinuous change of the adjusted power be moved to a higher frequency.

12. A device with a noise shaping function in gain control, comprising:
a first adder for generating a first value according to an input signal, a second value, and a third value;
a controller;
a signal generator;
an N-bit quantizer coupled to the first adder for outputting a codeword to a controller according to the first value, wherein the codeword is mapped to an adjusting order, adjusting orders corresponding to codewords outputted by the N-bit quantizer are between a smallest predetermined negative value and α largest positive predetermined value, the controller generates a control signal to the signal generator according to the adjusting order, the signal generator adjusts a current power of a signal to generate the signal with adjusted power according to the control signal, and N is an integer greater than 2;
a mapping circuit coupled to the N-bit quantizer for outputting a mapping value according to the codeword;
a second adder coupled to the first adder, the N-bit quantizer, and the mapping circuit for generating the second value according to the mapping value and the first value;
a first D flip-flop coupled to the second adder for latching the second value;
a scaler coupled to the first D flip-flop and the first adder for scaling the second value to generate the third value; and
a second D flip-flop coupled to the first adder, the scaler, and the first D flip-flop for latching the second value and outputting the second value to the first adder.
